(19) United States
(12) Patent Application Publication
(10) Pub. No.: US 2022/0149021 A1
(43) Pub. Date: May 12, 2022

(54) TILED DISPLAY DEVICE

(71) Applicant: Samsung Display Co., Ltd., Yongin-si (KR)

(72) Inventors: Wan Soon IM, Cheonan-si (KR); Chang Woo KWON, Seoul (KR)

(21) Appl. No.: 17/452,867

(22) Filed: Oct. 29, 2021

(30) Foreign Application Priority Data
Nov. 9, 2020 (KR) 10-2020-0148599

(51) Int. Cl. H01L 25/16

(52) U.S. Cl. CPC H01L 25/162; H01L 25/167

(57) ABSTRACT

A tiled display device includes a first display panel including a first lower structure including a first driver, and a first upper structure on the first lower structure, and a second display panel including a second lower structure that includes a second driver and that is adjacent to the first lower structure in a bonding area, and a second upper structure that is on the second lower structure and that is adjacent to the first upper structure, wherein the second lower structure at least partially overlaps the first upper structure, and wherein the first driver and the second driver are spaced apart from the bonding area in a plan view.

### CROSS-REFERENCE TO RELATED APPLICATION

This application claims priority to, and the benefit of, Korean Patent Application No. 10-2020-0148599 filed in the Korean Intellectual Property Office on Nov. 9, 2020, the entire contents of which are incorporated herein by reference.

### BACKGROUND

### 1. Field

The present disclosure relates to a tiled display device.

### 2. Description of the Related Art

A tiled display device includes a plurality of display panels bonded to each other to collectively implement a large screen. Respective display panels mentioned above are bonded to each other in a bonding area. However, when the display panels having a non-display area at an edge thereof are bonded to each other, a seam-line may be visible to a user. Due to this, display quality of the tiled display device may be deteriorated.

### SUMMARY

An aspect of the present disclosure is to provide a tiled display device with improved display quality. However, the aspect of the present disclosure is not limited to the above-described aspect, and may be variously extended without departing from the spirit and scope of the present disclosure.

Some embodiments provide a tiled display device including a first display panel including a first lower structure including a first driver, and a first upper structure on the first lower structure, and a second display panel including a second lower structure that includes a second driver and that is adjacent to the first lower structure in a bonding area, and a second upper structure that is on the second lower structure and that is adjacent to the first upper structure, wherein the second lower structure at least partially overlaps the first upper structure, and wherein the first driver and the second driver are spaced apart from the bonding area in a plan view.

The first lower structure may further include a plurality of first light emitting elements, wherein the second lower structure further includes a plurality of second light emitting elements, and wherein the bonding area is between the first light emitting elements adjacent to the second lower structure and the second light emitting elements adjacent to the first lower structure.

A size of a first area of the first lower structure may be the same as a size of a second area of the second lower structure in a plan view.

A size of a third area of the first upper structure may be larger than a size of a fourth area of the second upper structure in a plan view.

The second lower structure may further include a light emitting element, wherein the first upper structure includes a color conversion pattern, and wherein the light emitting element overlaps the color conversion pattern.

The light emitting element overlapping the color conversion pattern may be adjacent to the first lower structure.

The color conversion pattern overlapping the light emitting element may be adjacent to the second upper structure.

A size of a first area of the first lower structure may be smaller than a size of a second area of the second lower structure in a plan view.

A size of a third area of the first upper structure may be the same as a size of a fourth area of the second upper structure in a plan view.

A size of a third area of the first upper structure may be larger than a size of a fourth area of the second upper structure in a plan view.

Other embodiments provide a tiled display device including a first display panel including a first lower structure including a first driver, and a first upper structure on the first lower structure, a second display panel adjacent to the first display panel in a first direction and including a second lower structure that includes a second driver and that is adjacent to the first lower structure in a first bonding area, and a second upper structure that is on the second lower structure and that is adjacent to the first upper structure, a third display panel adjacent to the first display panel in a second direction crossing the first direction and including a third lower structure that includes a third driver and that is adjacent to the first lower structure in a second bonding area, and a third upper structure that is on the third lower structure and that is adjacent to the first upper structure, and a fourth display panel adjacent to the third display panel in the first direction and including a fourth lower structure that includes a fourth driver, that is adjacent to the second lower structure in a third bonding area, and that is adjacent to the third lower structure in a fourth bonding area, and a fourth upper structure that is on the fourth lower structure, and that is adjacent to the second and third upper structures, wherein the second lower structure at least partially overlaps the first upper structure, and wherein the first to fourth drivers are spaced apart from the first to fourth bonding areas, respectively, in a plan view.

The first lower structure may further include a plurality of first light emitting elements, the second lower structure further includes a plurality of second light emitting elements, the third lower structure further includes a plurality of third light emitting elements, and the fourth lower structure further includes a plurality of fourth light emitting elements, the first bonding area is between the first light emitting elements adjacent to the second lower structure and the second light emitting elements adjacent to the first lower structure, the second bonding area is between the first light emitting elements adjacent to the third lower structure and the third light emitting elements adjacent to the first lower structure, the third bonding area is between the second light emitting elements adjacent to the fourth lower structure and the fourth light emitting elements adjacent to the second lower structure, and the fourth bonding area is between the third light emitting elements adjacent to the fourth lower structure and the fourth lower structure adjacent to the third lower structure.

Sizes of respective areas of the first to fourth lower structures may be the same in a plan view.

A size of a first area of the first upper structure may be larger than a size of a second area of the second upper structure, may be larger than a size of a third area of the third upper structure, and may be larger than a size of a fourth area of the fourth upper structure in the plan view.

The size of the second area may be the same as the size of the third area.

The size of the fourth area may be smaller than the size of the second area, and may be smaller than the size of the third area.

A size of a first area of the first lower structure may be smaller than a size of a second area of the second lower structure, may be smaller than a size of a third area of the third lower structure, and may be smaller than a size of a fourth area of the fourth lower structure in a plan view.

Sizes of areas of the first to fourth upper structures may be the same in a plan view.

A size of a fifth area of the first upper structure may be larger than a size of a sixth area of the second upper structure, may be larger than a size of a seventh area of the third upper structure, and may be larger than a size of an eighth area of the fourth upper structure in a plan view.

The size of the sixth area may be the same as the size of the seventh area.

The tiled display device according to some embodiments of the present disclosure may include drivers spaced apart from bonding areas in a plan view. In addition, the tiled display device may include display panels overlapping each other. For example, a second lower structure of a second display panel and a first upper structure of a first display panel may overlap each other. Accordingly, a seam-line that may be viewed during a process in which the display panels are bonded to each other may not be viewed by a user of the end product. Therefore, the display quality of the tiled display device may be improved.

However, the aspects of the present disclosure are not limited to the above-described aspects, and may be variously extended without departing from the spirit and scope of the present disclosure.

### BRIEF DESCRIPTION OF THE DRAWINGS

FIG. 1 illustrates a block diagram of a tiled display device according to embodiments.

FIG. 2 illustrates a perspective view of a tiled display device according to some embodiments.

FIG. 3 illustrates a top plan view of tiled display device of FIG. 2.

FIG. 4 illustrates a cross-sectional view taken along the line I-I′ of FIG. 3.

FIG. 5 illustrates an enlarged view of an area “A” of FIG. 4.

FIG. 6 illustrates an enlarged view of an area “B” of FIG. 4.

FIG. 7 illustrates a top plan view of a tiled display device according to other embodiments.

FIG. 8 illustrates a cross-sectional view taken along the line II-II′ of FIG. 7.

FIG. 9 illustrates a top plan view of a tiled display device according to other embodiments.

FIG. 10 illustrates a cross-sectional view taken along the line III-III′ of FIG. 9.

### DETAILED DESCRIPTION

Aspects of some embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may be embodied in various different forms, and should not be construed as being limited to only the illustrated embodiments herein. Rather, these embodiments are provided as examples so that this disclosure will be thorough and complete, and will fully convey the aspects of the present disclosure to those skilled in the art. Accordingly, processes, elements, and techniques that are not necessary to those having ordinary skill in the art for a complete understanding of the aspects of the present disclosure may not be described.

Unless otherwise noted, like reference numerals, characters, or combinations thereof denote like elements throughout the attached drawings and the written description, and thus, descriptions thereof will not be repeated. Further, parts not related to the description of the embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the particular illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form in order to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

The electronic or electric devices and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the embodiments of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

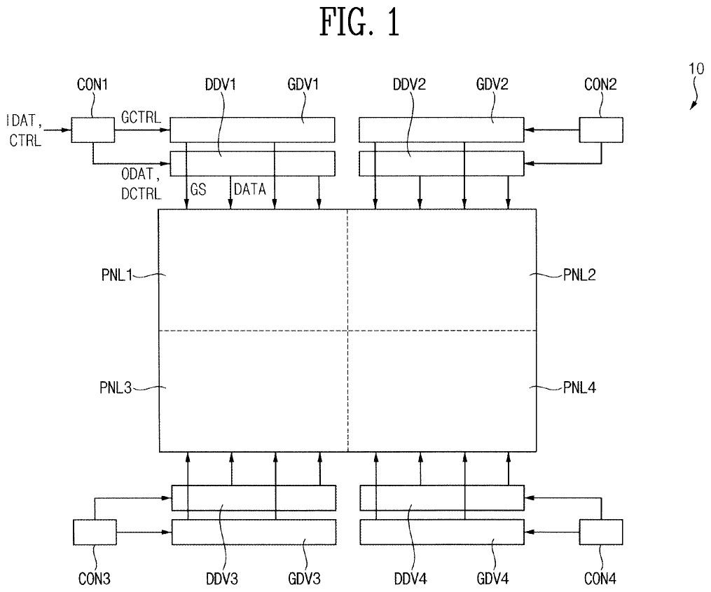

FIG. 1 illustrates a block diagram of a tiled display device according to embodiments.

Referring to FIG. 1, a tiled display device 10 according to some embodiments may include a plurality of display panels. The display panels may each include a controller and a plurality of drivers. The drivers may each include a plurality of gate drivers and a plurality of data drivers.

In some embodiments, the tiled display device 10 may include a first display panel PNL1, a second display panel PNL2, a third display panel PNL3, and a fourth display panel PNL4.

The first display panel PNL1 may display a first image, the second display panel PNL2 may display a second image, the third display panel PNL3 may display a third image, and the fourth display panel PNL4 may display a fourth image. A user may watch an image in which the first to fourth images are combined. In some embodiments, the first to fourth display panels PNL1, PNL2, PNL3, and PNL4 may have the substantially same structure.

In some embodiments, the tiled display device 10 may include a first gate driver GDV1, a second gate driver GDV2, a third gate driver GDV3, and a fourth gate driver GDV4. Hereinafter, the first gate driver GDV1 will be mainly described, and each of the second to fourth gate drivers GDV2, GDV3, and GDV4 may substantially correspond to the first gate driver GDV1.

The first gate driver GDV1 may generate a gate signal GS. The gate signal GS may be provided to the first display panel PNL1 through gate wires. The gate signal GS may turn on or off transistors included in the first display panel PNL1. For example, the first gate driver GDV1 may be implemented as an integrated circuit, but the present disclosure is not limited thereto.

In some embodiments, the tiled display device 10 may include a first data driver DDV1, a second data driver DDV2, a third data driver DDV3, and a fourth data driver DDV4. Hereinafter, the first data driver DDV1 will be mainly described, and each of the second to fourth data drivers DDV2, DDV3, and DDV4 may substantially correspond to the first data driver DDV1.

The first data driver GDV1 may generate a data voltage DATA. The data voltage DATA may be provided to the first display panel PNL1 through data wires. The data voltage DATA may be provided to the transistors, and the transistors may provide a driving current to light emitting elements included in the first display panel PNL1. For example, the first data driver DDV1 may be implemented as an integrated circuit, but the present disclosure is not limited thereto.

In some embodiments, the tiled display device 10 may include a first controller CON1, a second controller CON2, a third controller CON3, and a fourth controller CON4. Hereinafter, the first controller CON1 will be mainly described, and each of the second to fourth controllers CON2, CON3, and CON4 may substantially correspond to the first controller CON1.

The first controller CON1 may control the first gate driver GDV1 and the first data driver DDV1. For example, the first controller CON1 may receive a control signal CTRL and input image data IDAT, and may generate a gate control signal GCTRL, a data control signal DCTRL, and image data ODAT. The gate control signal GCTRL may be provided to the first gate driver GDV1, and the data control signal DCTRL and the image data ODAT may be provided to the data driver DDV. For example, the first controller CON1 may be located on the flexible printed circuit board, but the present disclosure is not limited thereto.

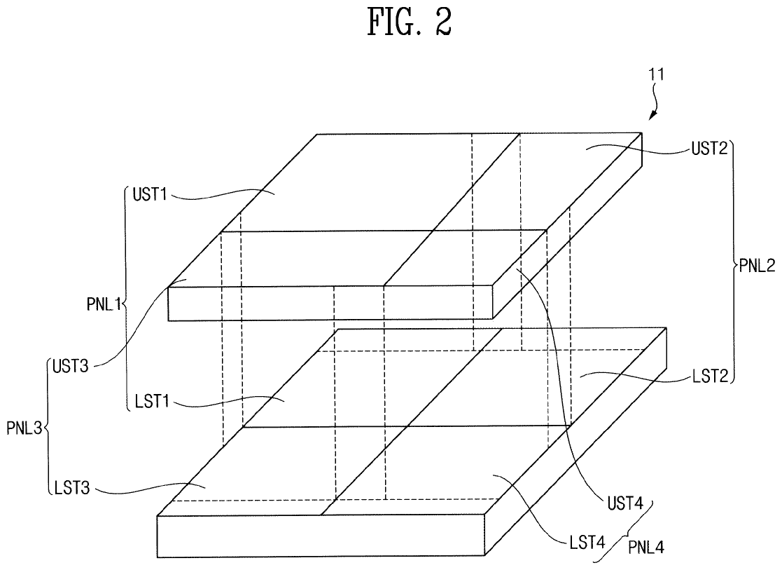

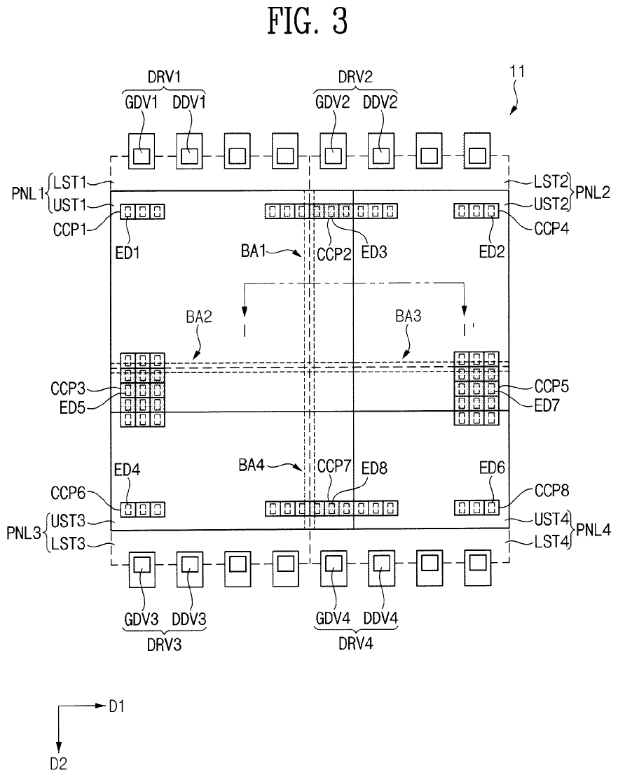

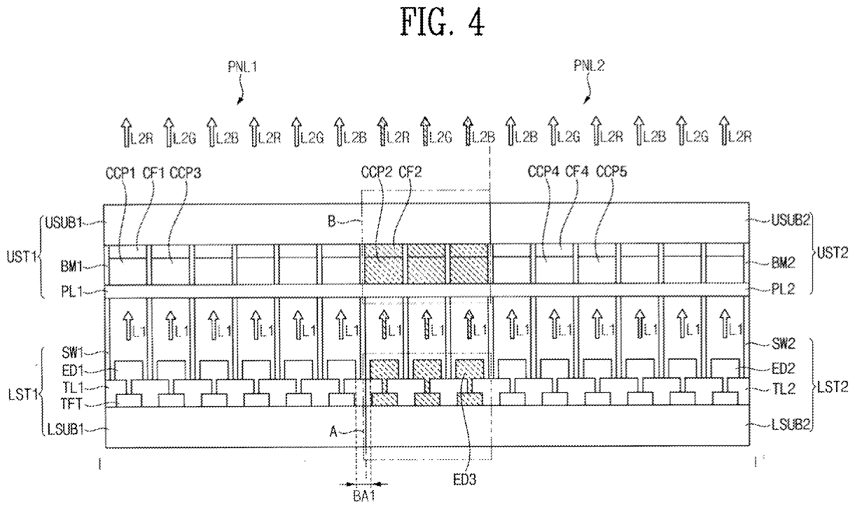

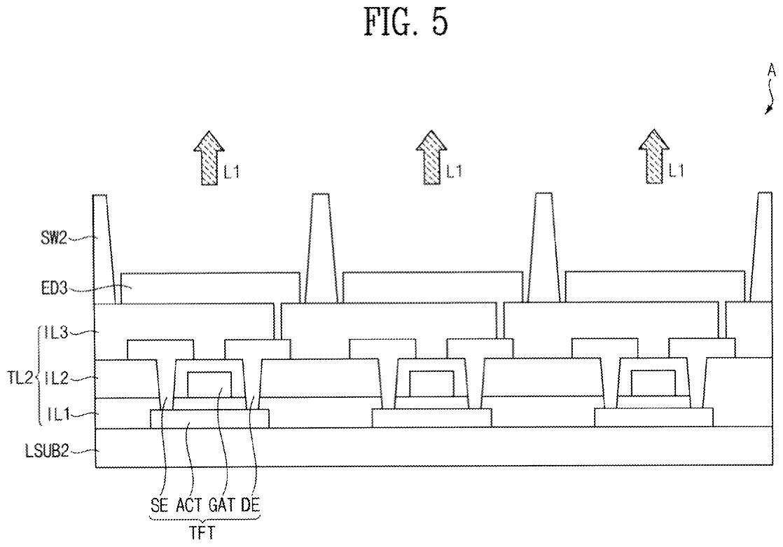

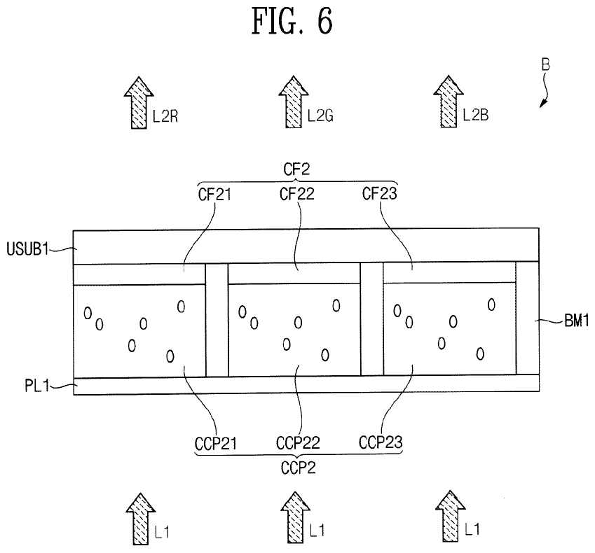

FIG. 2 illustrates a perspective view of a tiled display device according to some embodiments, FIG. 3 illustrates a top plan view of tiled display device of FIG. 2, FIG. 4 illustrates a cross-sectional view taken along the line I-I′ of FIG. 3, FIG. 5 illustrates an enlarged view of an area “A” of FIG. 4, and FIG. 6 illustrates an enlarged view of an area “B” of FIG. 4.

Referring to FIG. 2, FIG. 3, and FIG. 4, a tiled display device 11 according to some embodiments may include the first to fourth display panels PNL1, PNL2, PNL3, and PNL4. The first to fourth display panels PNL1, PNL2, PNL3, and PNL4 include first to fourth lower structures LST1, LST2, LST3, and LST4 and first to fourth upper structures UST1, UST2, UST3, and UST4, respectively. The first to fourth lower structures LST1, LST2, LST3, and LST4 may include a plurality of light emitting elements and the first to fourth drivers DRV1, DRV2, DRV3, and DRV4, respectively. The first to fourth drivers DRV1, DRV2, DRV3, and DRV4 include the first to fourth gate drivers GDV1, GDV2, GDV3, and GDV4 and the first to fourth data drivers DDV1, DDV2, DDV3, and DDV4, respectively.

Referring to FIG. 4 and FIG. 5, the second lower structure LST2 may include a second lower substrate LSUB2, a second transistor layer TL2, at least one second light emitting element ED2, at least one third light emitting element ED3, and at least one second wall SW2.

The first lower structure LST1 may include a first lower substrate LST1, a first transistor layer TL1, at least one first light emitting element ED1, and at least one first wall SW1.

In some embodiments, the first lower structure LST1 may have a structure that is substantially equivalent to the second lower structure LST2. Hereinafter, the second lower structure LST2 will be described.

The second lower substrate LSUB2 may include glass, quartz, plastic, or the like. In some embodiments, the second lower substrate LSUB2 may be a glass substrate including glass. Accordingly, the tiled display device 11 may be implemented as a rigid display device.

The second transistor layer TL2 may be located on the second lower substrate LSUB2. The second transistor layer TL2 may include at least one transistor TFT and a plurality of insulation layers. The transistor TFT may include an active pattern ACT, a gate electrode GAT, a source electrode SE, and a drain electrode DE. The transistor TFT may be electrically connected to the first driver DRV1. The transistor TFT may operate according to the gate signal GS, and may generate the driving current according to the data voltage DATA.

For example, the active pattern ACT may be located on the second lower substrate LSUB2. In some embodiments, the active pattern ACT may include an oxide semiconductor (for example, indium tin oxide (ITO), etc.). In other embodiments, the active pattern ACT may include a silicon semiconductor.

A first insulation layer IL1 may cover the active pattern ACT, and may be located on the second lower substrate LSUB2. For example, the first insulation layer IL1 may include an insulation material (for example, silicon oxide (SiOx), silicon nitride (SiNx), silicon oxynitride (SiOxNy), etc.).

The gate electrode GAT may be located on the first insulation layer IL1. For example, the gate electrode GAT may include a metallic material (for example, molybdenum (Mo)).

A second insulation layer IL2 may cover the gate electrode GAT, and may be located on the first insulation layer IL1. For example, the second insulation layer IL2 may include an insulation material.

The source electrode SE and the drain electrode DE may be located on the second insulation layer IL2. The source electrode SE and the drain electrode DE may contact the active pattern ACT, respectively. For example, the source and drain electrodes SE and DE may include a metallic material.

A third insulation layer IL3 may cover the source and drain electrodes SE and DE, and may be located on the second insulation layer IL2. The third insulation layer IL3 may include an insulation material, and may have a flat upper surface.

The second and third light emitting elements ED2 and ED3 may be located on the third insulation layer IL3. For example, the second and third light emitting elements ED2 and ED3 may emit blue light L1.

In some embodiments, the second and third light emitting elements ED2 and ED3 may be nano light emitting diodes NED. For example, the second and third light emitting elements ED2 and ED3 may include an inorganic light emitting material (for example, gallium nitrate (GaN)). However, the present disclosure is not limited thereto, and the second and third light emitting elements ED2 and ED3 may include various light emitting materials.

The second wall SW2 may be located on the second transistor layer TL2. The second wall SW2 may be adjacent to the second and third light emitting elements ED2 and ED3. The second wall SW2 may partition light emitting areas of the second and third light emitting elements ED2 and ED3, and may support the second upper structure UST2.

Referring to FIG. 4 and FIG. 6, the first upper structure UST1 may include a first passivation layer PL1, at least one first light blocking pattern BM1, at least one first color conversion pattern CCP1, at least one first color filter CF1, at least one second color conversion pattern CCP2, at least one second color filter CF2, at least one third color conversion pattern CCP3, at least one third color filter, and a first upper substrate USUB1.

The second upper structure UST2 may include a first passivation layer PL2, at least one second light blocking pattern BM2, at least one fourth color conversion pattern CCP4, at least one fourth color filter, at least one fifth color conversion pattern CCP5, at least one fifth color filter, and a second upper substrate USUB2.

In some embodiments, the second upper structure UST2 may have a structure substantially equivalent to the first upper structure UST1. Hereinafter, the first upper structure LST1 will be described.

The first upper substrate USUB1 may include glass, quartz, plastic, or the like. In some embodiments, the first upper substrate USUB1 may be a glass substrate including glass. Accordingly, the tiled display device 11 may be implemented as a rigid display device.

The first light blocking pattern BM1 may be located under the first upper substrate USUB1. The first light blocking pattern BM1 may partition the light emitting area of the first display panel PNL1, and may prevent color mixing. For example, the first light blocking pattern BM1 may block light.

The first and second color filters CF1 and CF2 may be located under the first upper substrate USUB1. The first and second color filters CF1 and CF2 may be adjacent to the first light blocking pattern BM1.

In some embodiments, the second color filter CF2 may be adjacent to the second upper structure UST2, and may overlap the second lower structure LST2. The first color filter CF1 may be spaced apart from the second upper structure UST2, and might not overlap the second lower structure LST2.

In some embodiments, each of the first and second color filters CF1 and CF2 may include a red color filter, a green color filter, and a blue color filter. For example, the second color filter CF2 may include a red color filter CF21, a green color filter CF22, and a blue color filter CF23. The red color filter CF21 may transmit red light, the green color filter CF22 may transmit green light, and the blue color filter CF23 may transmit blue light.

The first and second color conversion patterns CCP1 and CCP2 may be located under the first and second color filters CF1 and CF2, respectively. The first and second color conversion patterns CCP1 and CCP2 may be adjacent to the first light blocking pattern BM1.

In some embodiments, the second color conversion pattern CCP2 may be adjacent to the second upper structure UST2, and may overlap the second lower structure LST2. The first color conversion pattern CCP1 may be spaced apart from the second upper structure UST2, and might not overlap the second lower structure LST2.

In some embodiments, each of the first and second color conversion patterns CCP1 and CCP2 may include a red color conversion pattern, a green color conversion pattern, and a scattering pattern. For example, the second color conversion pattern CCP2 may include a red color conversion pattern CCP21, a green color conversion pattern CCP22, and a scattering pattern CCP23.

For example, the red color conversion pattern CCP21 may convert the blue light L1 into red light L2R, the green color conversion pattern CCP22 may convert the blue light L1 into green light L2G, and the scattering pattern CCP23 may scatter the blue light L1 into blue light L2G.

For example, the red color conversion pattern CCP21 and the green color conversion pattern CCP22 may include wavelength conversion particles. The wavelength conversion particles may include quantum dots, may absorb incident light, and may emit light having a wavelength that is different from that of the incident light. In addition, the scattering pattern CCP23 may include a scatterer. The scatterer may scatter the incident light, and accordingly, an optical path of the incident light may be increased. The scatterer may include a metal oxide or organic material. For example, the metal oxide may include a titanium oxide (TiO₂), a zirconium oxide (ZrO₂), an aluminum oxide (Al₂O₃), an indium oxide (In₂O₃), a zinc oxide (ZnO), a tin oxide (SnO₂), and the like, and the organic material may include an acryl-based resin or urethane-based resin.

The first passivation layer PL1 may be located at the lowermost portion of the first upper structure UST1. For example, the first passivation layer PL1 may include an inorganic material (for example, silicon oxide (SiOₓ), silicon nitride (SiNₓ), silicon oxynitride (SiOₓN_{y}), etc.).

In some embodiments, the second lower structure LST2 may be adjacent to the first lower structure LST1 in a first bonding area BA1. For example, the second lower structure LST2 may be bonded to the first lower structure LST1 in the first bonding area BA1. The first bonding area BA1 may be an area between the first light emitting element ED1 that is closest to the second lower structure LST2 and the third light emitting element ED3 that is closest to the first lower structure LST1.

In addition, the first and second drivers DRV1 and DRV2 may be spaced apart from the first bonding area BA1 in a plan view. For example, the first and second drivers DRV1 and DRV2 might not overlap the first bonding area BA1.

In some embodiments, as shown in FIG. 3, the first and second drivers DRV1 and DRV2 may be located at protruding portions of the first and second lower structures LST1 and LST2, respectively. In addition, the first and second drivers DRV1 and DRV2 may be located together at one end portion.

In other embodiments, the first and second drivers DRV1 and DRV2 may be located at lower portions of first and second lower substrates LSUB1 and LSUB2 (for example, lower surfaces of the first and second lower substrates LSUB1 and LSUB2), respectively. In other words, each of the first and second display panels PNL1 and PNL2 may have a back-bonding structure.

Referring back to FIG. 2 and FIG. 3, the first to fourth display panels PNL1, PNL2, PNL3, and PNL4 may cross each other. For example, the first to fourth bonding areas in which the first to fourth lower structures LST1, LST2, LST3, and LST4 are bonded to each other, and the bonding areas in which the first to fourth upper structures UST1, UST2, UST3, and UST4 are bonded to each other, might not overlap each other, as will be described in detail below.

The first lower structure LST1 may include the first light emitting element ED1. The second lower structure LST2 may include the second and third light emitting elements ED2 and ED3. The third lower structure LST3 may include fourth and fifth light emitting elements ED4 and ED5. The fourth lower structure LST4 may include sixth to eighth light emitting elements ED6, ED7, and ED8.

The first upper structure UST1 may include the first to third color conversion patterns CCP1, CCP2, and CCP3. The second upper structure UST2 may include the fourth and fifth color conversion patterns CCP4 and CCP5. The third upper structure UST3 may include sixth and seventh color conversion patterns CCP6 and CCP7. The fourth upper structure UST4 may include eighth color conversion pattern CCP8.

In some embodiments, the second lower structure LST2 may at least partially overlap the first upper structure UST1. For example, the third light emitting element ED3 included in the second lower structure LST2 may overlap the second color conversion pattern CCP2 included in the first upper structure UST1.

Accordingly, the blue light L1 emitted from the third light emitting element ED3 may proceed to the second color conversion pattern CCP2, and may be converted to the red light L2R, the green light L2G, or the blue light L2B by the second color conversion pattern CCP2.

In some embodiments, the third lower structure LST3 may at least partially overlap the first upper structure UST1. For example, the fifth light emitting element ED5 included in the third lower structure LST3 may overlap the third color conversion pattern CCP3 included in the first upper structure UST1.

Accordingly, the blue light L1 emitted from the fifth light emitting element ED5 may proceed to the third color conversion pattern CCP3, and may be converted to the red light L2R, the green light L2G, or the blue light L2B by the third color conversion pattern CCP3.

In some embodiments, the fourth lower structure LST4 may at least partially overlap the second upper structure UST2. For example, the seventh light emitting element ED7 included in the fourth lower structure LST4 may overlap the fifth color conversion pattern CCP5 included in the second upper structure UST2.

Accordingly, the blue light L1 emitted from the seventh light emitting element ED7 may proceed to the fifth color conversion pattern CCP5, and may be converted to the red light L2R, the green light L2G, or the blue light L2B by the fifth color conversion pattern CCP5.

In some embodiments, the fourth lower structure LST4 may at least partially overlap the third upper structure UST3. For example, the eighth light emitting element ED8 included in the fourth lower structure LST4 may overlap the seventh color conversion pattern CCP7 included in the third upper structure UST3.

Accordingly, the blue light L1 emitted from the eighth light emitting element ED8 may proceed to the seventh color conversion pattern CCP7, and may be converted to the red light L2R, the green light L2G, or the blue light L2B by the seventh color conversion pattern CCP7.

In some embodiments, for the first to fourth display panels PNL1, PNL2, PNL3, and PNL4 to cross each other, areas of the first to fourth lower structures LST1, LST2, LST3, and LST4 and areas of the first to fourth upper structures UST1, UST2, UST3, and UST4 may be set.

For example, as shown in FIG. 2 and FIG. 3, when viewed in a plan view, the areas of the first to fourth lower structures LST1, LST2, LST3, and LST4 may be substantially the same.

For example, as shown in FIG. 2 and FIG. 3, when viewed in a plan view, the first area of the first upper structure UST1 may be larger than the second area of the second upper structure UST2, and may be larger than the third area of the third upper structure UST3, and may be larger than the fourth area of the fourth upper structure UST4. In addition, the second area may be the same as the third area.

In addition, the first to fourth lower structures LST1, LST2, LST3, and LST4 may be adjacent in the first to fourth bonding areas BA1, BA2, BA3, and BA4, respectively. For example, the first and second lower structures LST1 and LST2 may be bonded in the first bonding area BA1, the first and third lower structures LST1 and LST3 may be bonded in the second bonding area BA2, the second and fourth lower structures LST2 and LST4 may be bonded in the third bonding area BA3, and the third and fourth lower structures LST3 and LST4 may be bonded in the fourth bonding area BA4.

In some embodiments, the first to fourth drivers DRV1, DRV2, DRV3, and DRV4 may be spaced apart from the first to fourth bonding areas BA1, BA2, BA3, and BA4 in a plan view. For example, the first to fourth drivers DRV1, DRV2, DRV3, and DRV4 might not overlap the first to fourth bonding areas BA1, BA2, BA3, and BA4.

The tiled display device 11 according to some embodiments may include the first to fourth drivers DRV1, DRV2, DRV3, and DRV4 spaced apart from the first to fourth bonding areas BA1, BA2, BA3, and BA4 in a plan view. In addition, the tiled display device 11 may include the first to fourth display panels PNL1, PNL2, PNL3, and PNL4 crossing each other. Accordingly, as the first to fourth display panels PNL1, PNL2, PNL3, and PNL4 are bonded to each other, a seam-line that would otherwise be viewed might not be visible to a user. Therefore, the display quality of the tiled display device 11 may be improved.

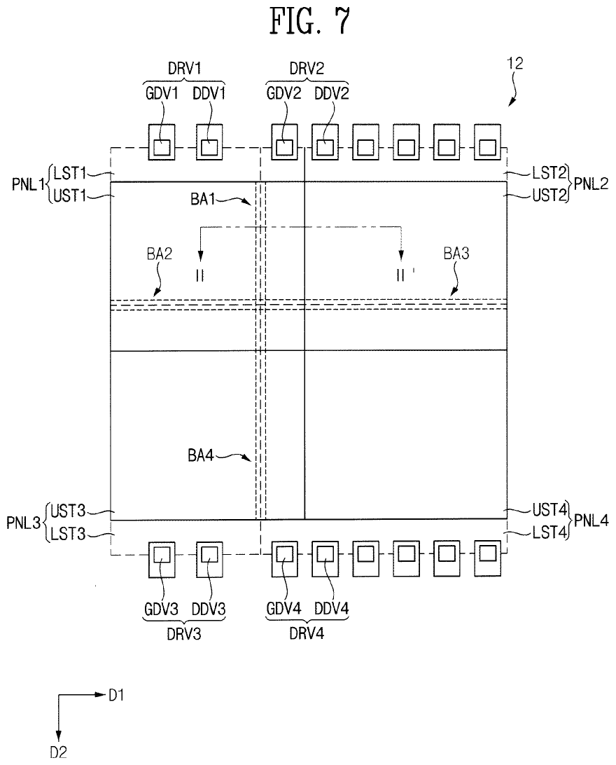

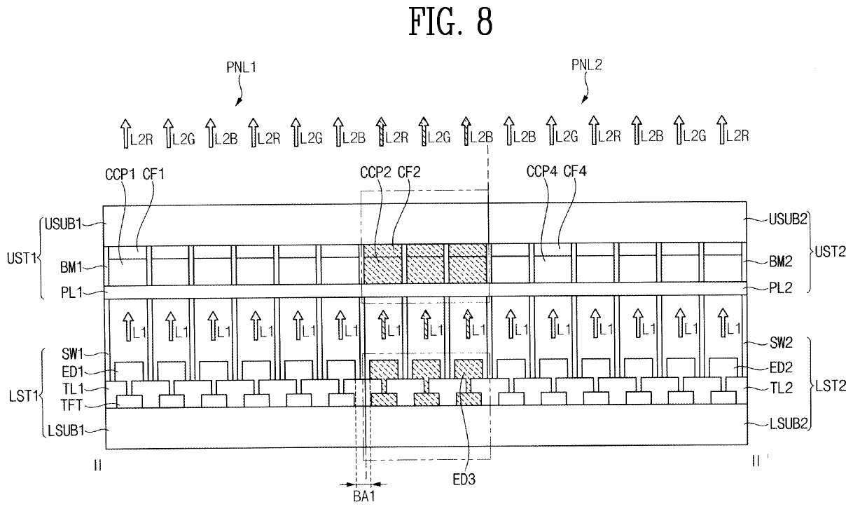

FIG. 7 illustrates a top plan view of a tiled display device according to other embodiments, and FIG. 8 illustrates a cross-sectional view taken along the line II-II′ of FIG. 7.

Referring to FIG. 7 and FIG. 8, a tiled display device 12 according to other embodiments may include first to fourth display panels PNL1, PNL2, PNL3, and PNL4. The first to fourth display panels PNL1, PNL2, PNL3, and PNL4 include first to fourth lower structures LST1, LST2, LST3, and LST4 and first to fourth upper structures UST1, UST2, UST3, and UST4, respectively. However, the tiled display device 12 may be substantially equivalent to the tiled display device 11 described above, except for areas of structures.

In some embodiments, for the first to fourth display panels PNL1, PNL2, PNL3, and PNL4 to cross each other, areas of the first to fourth lower structures LST1, LST2, LST3, and LST4 and areas of the first to fourth upper structures UST1, UST2, UST3, and UST4 may be set.

For example, as shown in FIG. 7, when viewed in a plan view, the first area of the first lower structure LST1 may be smaller than the second area of the second lower structure LST2, may be smaller than the third area of the third lower structure LST3, and may be smaller than the fourth area of the fourth lower structure LST4. In addition, the second area may be the same as the third area.

For example, as shown in FIG. 7, when viewed in a plan view, the areas of the first to fourth upper structures UST1, UST2, UST3, and UST4 may be the same.

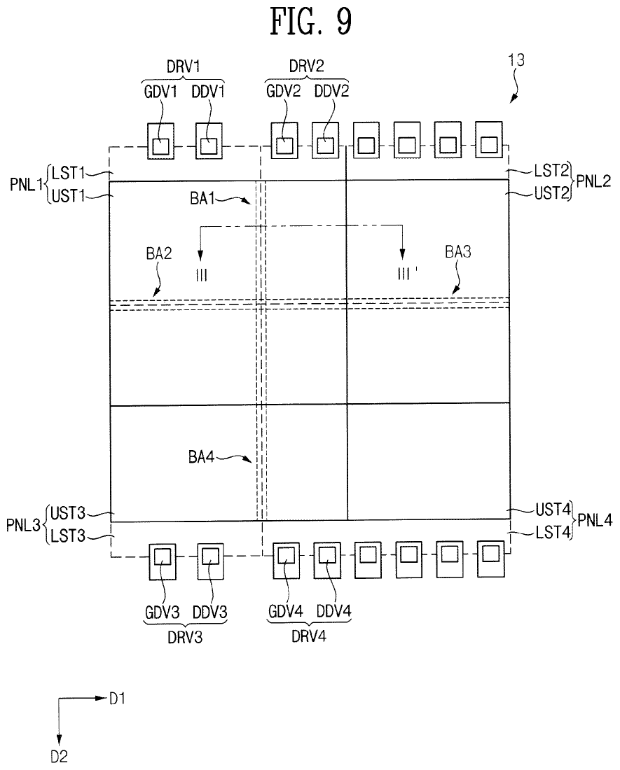

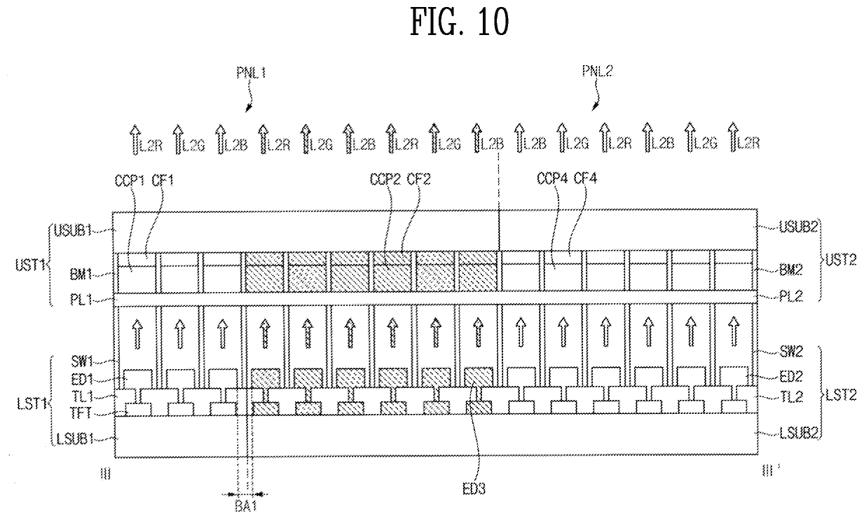

FIG. 9 illustrates a top plan view of a tiled display device according to other embodiments, an FIG. 10 illustrates a cross-sectional view taken along the line III-III′ of FIG. 9.

Referring to FIG. 9 and FIG. 10, a tiled display device 13 according to other embodiments may include first to fourth display panels PNL1, PNL2, PNL3, and PNL4. The first to fourth display panels PNL1, PNL2, PNL3, and PNL4 include first to fourth lower structures LST1, LST2, LST3, and LST4 and first to fourth upper structures UST1, UST2, UST3, and UST4, respectively. However, the tiled display device 13 may be substantially the same as the tiled display device 11 described above, except for areas of structures and the number of overlapping light emitting elements.

In some embodiments, for the first to fourth display panels PNL1, PNL2, PNL3, and PNL4 to cross each other, areas of the first to fourth lower structures LST1, LST2, LST3, and LST4 and areas of the first to fourth upper structures UST1, UST2, UST3, and UST4 may be set.

For example, as shown in FIG. 9, when viewed in a plan view, the first area of the first lower structure LST1 may be smaller than the second area of the second lower structure LST2, may be smaller than the third area of the third lower structure LST3, and may be smaller than the fourth area of the fourth lower structure LST4. In addition, the second area may be the same as the third area. In other words, the areas of the first to fourth lower structures LST1, LST2, LST3, and LST4 included in the tiled display device 13 may be substantially the same as the areas of the first to fourth lower structures LST1, LST2, LST3, and LST4 included in the tiled display device 12 described above with reference to FIG. 7.

For example, as shown in FIG. 9, when viewed in a plan view, the first area of the first upper structure UST1 may be larger than the second area of the second upper structure UST2, and may be larger than the third area of the third upper structure UST3, and may be larger than the fourth area of the fourth upper structure UST4. In addition, the second area may be the same as the third area. In other words, the areas of the first to fourth upper structures UST1, UST2, UST3, and UST4 included in the tiled display device 13 may be substantially the same as the areas of the first to fourth upper structures UST1, UST2, UST3, and UST4 described above with reference to FIG. 3.

Accordingly, as shown in FIG. 10, a larger number of light emitting elements may overlap the color conversion patterns. For example, the third light emitting element ED3 may overlap the second color conversion pattern CCP2. As the area in which the second lower structure LST2 and the first upper structure UST1 overlap each other increases, the number of the third light emitting element ED3 may increase.

The tiled display device according to some embodiments may include the first to fourth drivers spaced apart from the first to fourth bonding areas in a plan view. In addition, the tiled display device may include the first to fourth display panels crossing each other. For example, the second lower structure of the second display panel and the first upper structure of the first display panel may overlap each other. Accordingly, as the first to fourth display panels are bonded to each other, a seam-line that would otherwise be visible might not be seen by a user. Therefore, the display quality of the tiled display device may be improved.

The present disclosure may be applied to a display device and an electronic device including the same. For example, the present disclosure may be applied to a high resolution smart phone, a mobile phone, a smart pad, a smart watch, a tablet PC, a vehicle navigation system, a television, a computer monitor, a laptop computer, and the like.

While the present disclosure has been described in connection with what is presently considered to be practical embodiments, it is to be understood that the present disclosure is not limited to the disclosed embodiments, but, on the contrary, is intended to cover various modifications and equivalent arrangements included within the spirit and scope of the appended claims, with functional equivalents thereof to be included therein.

What is claimed is:

1. A tiled display device comprising:
a first display panel comprising a first lower structure comprising a first driver, and a first upper structure on the first lower structure; and
a second display panel comprising a second lower structure that comprises a second driver and that is adjacent to the first lower structure in a bonding area, and a second upper structure that is on the second lower structure and that is adjacent to the first upper structure,
wherein the second lower structure at least partially overlaps the first upper structure, and
wherein the first driver and the second driver are spaced apart from the bonding area in a plan view.

2. The tiled display device of claim 1, wherein the first lower structure further comprises a plurality of first light emitting elements,
wherein the second lower structure further comprises a plurality of second light emitting elements, and
wherein the bonding area is between the first light emitting elements adjacent to the second lower structure and the second light emitting elements adjacent to the first lower structure.

3. The tiled display device of claim 1, wherein a size of a first area of the first lower structure is the same as a size of a second area of the second lower structure in a plan view.

4. The tiled display device of claim 3, wherein a size of a third area of the first upper structure is larger than a size of a fourth area of the second upper structure in a plan view.

5. The tiled display device of claim 1, wherein the second lower structure further comprises a light emitting element,
wherein the first upper structure comprises a color conversion pattern, and
wherein the light emitting element overlaps the color conversion pattern.

6. The tiled display device of claim 5, wherein the light emitting element overlapping the color conversion pattern is adjacent to the first lower structure.

7. The tiled display device of claim 5, wherein the color conversion pattern overlapping the light emitting element is adjacent to the second upper structure.

8. The tiled display device of claim 1, wherein a size of a first area of the first lower structure is smaller than a size of a second area of the second lower structure in a plan view.

9. The tiled display device of claim 8, wherein a size of a third area of the first upper structure is the same as a size of a fourth area of the second upper structure in a plan view.

10. The tiled display device of claim 8, wherein a size of a third area of the first upper structure is larger than a size of a fourth area of the second upper structure in a plan view.

11. A tiled display device comprising:
a first display panel comprising a first lower structure comprising a first driver, and a first upper structure on the first lower structure;
a second display panel adjacent to the first display panel in a first direction and comprising a second lower structure that comprises a second driver and that is adjacent to the first lower structure in a first bonding area, and a second upper structure that is on the second lower structure and that is adjacent to the first upper structure;
a third display panel adjacent to the first display panel in a second direction crossing the first direction and comprising a third lower structure that comprises a third driver and that is adjacent to the first lower structure in a second bonding area, and a third upper structure that is on the third lower structure and that is adjacent to the first upper structure; and
a fourth display panel adjacent to the third display panel in the first direction and comprising a fourth lower structure that comprises a fourth driver, that is adjacent to the second lower structure in a third bonding area, and that is adjacent to the third lower structure in a fourth bonding area, and a fourth upper structure that is on the fourth lower structure, and that is adjacent to the second and third upper structures,
wherein the second lower structure at least partially overlaps the first upper structure, and
wherein the first to fourth drivers are spaced apart from the first to fourth bonding areas, respectively, in a plan view.

12. The tiled display device of claim 11, wherein the first lower structure further comprises a plurality of first light emitting elements, the second lower structure further comprises a plurality of second light emitting elements, the third lower structure further comprises a plurality of third light emitting elements, and the fourth lower structure further comprises a plurality of fourth light emitting elements;
the first bonding area is between the first light emitting elements adjacent to the second lower structure and the second light emitting elements adjacent to the first lower structure;
the second bonding area is between the first light emitting elements adjacent to the third lower structure and the third light emitting elements adjacent to the first lower structure;
the third bonding area is between the second light emitting elements adjacent to the fourth lower structure and the fourth light emitting elements adjacent to the second lower structure; and
the fourth bonding area is between the third light emitting elements adjacent to the fourth lower structure and the fourth lower structure adjacent to the third lower structure.

13. The tiled display device of claim 11, wherein sizes of respective areas of the first to fourth lower structures are the same in a plan view.

14. The tiled display device of claim 13, wherein a size of a first area of the first upper structure is larger than a size of a second area of the second upper structure, is larger than a size of a third area of the third upper structure, and is larger than a size of a fourth area of the fourth upper structure in the plan view.

15. The tiled display device of claim 14, wherein the size of the second area is the same as the size of the third area.

16. The tiled display device of claim 14, wherein the size of the fourth area is smaller than the size of the second area, and is smaller than the size of the third area.

17. The tiled display device of claim 11, wherein a size of a first area of the first lower structure is smaller than a size of a second area of the second lower structure, is smaller than a size of a third area of the third lower structure, and is smaller than a size of a fourth area of the fourth lower structure in a plan view.

18. The tiled display device of claim 17, wherein sizes of areas of the first to fourth upper structures are the same in a plan view.

19. The tiled display device of claim 17, wherein a size of a fifth area of the first upper structure is larger than a size of a sixth area of the second upper structure, is larger than a size of a seventh area of the third upper structure, and is larger than a size of an eighth area of the fourth upper structure in a plan view.

20. The tiled display device of claim 19, wherein the size of the sixth area is the same as the size of the seventh area.
